(19) United States
(12) Patent Application Publication
(10) Pub. No.: US 2025/0261428 A1
(43) Pub. Date: Aug. 14, 2025

(54) SEMICONDUCTOR DEVICES

(71) Applicant: Samsung Electronics Co., Ltd., Suwon-si (KR)

(72) Inventors: Seonbae Kim, Suwon-si (KR); Taeyong Kwon, Suwon-si (KR); Daesik Kim, Suwon-si (KR); Changhee Kim, Suwon-si (KR); Seunghyun Oh, Suwon-si (KR); Jimin Yu, Suwon-si (KR)

(21) Appl. No.: 18/909,207

(22) Filed: Oct. 8, 2024

(30) Foreign Application Priority Data
Feb. 8, 2024 (KR) 10-2024-0019855

(51) Int. Cl. H01L 29/417; H01L 29/06; H01L 29/423; H01L 29/66; H01L 29/775; H01L 29/786

(52) U.S. Cl. CPC H10D 64/258; H10D 30/014; H10D 30/43; H10D 30/6729; H10D 30/6735; H10D 30/6757; H10D 62/121; H10D 64/017

(57) ABSTRACT

A semiconductor device includes an active region extending in a first direction on a substrate, a plurality of channel layers spaced apart from each other in a vertical direction, a gate structure including a gate electrode intersecting the active region and the plurality of channel layers on the substrate and extending around ones of the plurality of channel layers, a gate spacer on side surfaces of the gate electrode, and a gate capping layer on the gate electrode and the gate spacer, a source/drain region on the active region on at least one side of the gate structure and in contact with the plurality of channel layers, and a contact structure on the source/drain region on a side of the gate structure, and electrically connected to the source/drain region. An upper region of the gate capping layer has an end with a rounded upper surface.

### CROSS-REFERENCE TO RELATED APPLICATION(S)

The application claims benefit of priority to Korean Patent Application No. 10-2024-0019855 filed on Feb. 8, 2024, in the Korean Intellectual Property Office, the disclosure of which is incorporated herein by reference in its entirety.

### BACKGROUND

Example embodiments in the example embodiment relate to a semiconductor device.

As demand for high performance, high speed, and/or multifunctionality of a semiconductor device increases, integration density of a semiconductor device has increased. In manufacturing a semiconductor device having a fine pattern in response to the trend of high integration density of a semiconductor device, it may be desired to implement patterns having a fine width or a fine spacing.

### SUMMARY

Example embodiments of the present disclosure provide a semiconductor device including a stopper layer having a step difference to prevent shorts between a contact structure connected to a source/drain region and a gate contact structure connected to a gate electrode.

According to example embodiments, a semiconductor device includes an active region that extends in a first direction on a substrate, a plurality of channel layers on the active region, wherein the plurality of channel layers are spaced apart from each other in a vertical direction perpendicular to an upper surface of the substrate, a gate structure intersecting the active region and the plurality of channel layers, the gate structure extends around ones of the plurality of channel layers, and extends in a second direction, wherein the gate structure includes, in a region overlapping the plurality of channel layers in the vertical direction, lower portions below the plurality of channel layers, respectively, and an upper portion on an uppermost channel layer among the plurality of channel layers, and including a gate electrode and a gate capping layer on the gate electrode, a source/drain region on the active region on at least a first side of the gate structure and in contact with the ones of the plurality of channel layers, a contact structure on the source/drain region on at least the first side of the gate structure, electrically connected to the source/drain region, and extends in the second direction, a stopper layer on the upper portion of the gate structure and on the contact structure, wherein the stopper layer includes a first portion on the gate capping layer, a second portion on the contact structure, and at least one third portion on an edge portion of the gate capping layer and electrically connecting the first portion to the second portion, and a gate contact structure that extends into the first portion of the stopper layer and the gate capping layer of the upper portion of the gate structure, and is electrically connected to the gate electrode of the gate structure. The at least one third portion has an inclined portion that is inclined with respect to an upper surface of the contact structure.

According to example embodiments, a semiconductor device includes an active region that extends in a first direction on a substrate, a plurality of channel layers spaced apart from each other in a vertical direction perpendicular to an upper surface of the substrate on the active region, a gate structure including a gate electrode that intersects the active region and the plurality of channel layers on the substrate and extends around ones of the plurality of channel layers, a gate spacer on side surfaces of the gate electrode, and a gate capping layer on the gate electrode and the gate spacer, and the gate structure extends in a second direction, a source/drain region on the active region on at least a first side of the gate structure and in contact with the ones of the plurality of channel layers, and a contact structure on the source/drain region on the first side of the gate structure, electrically connected to the source/drain region, and extends in the second direction, wherein an upper region of the gate capping layer of the gate structure has a first region, and a second region on at least one end of the first region and has a rounded upper surface.

According to example embodiments, a semiconductor device includes an active region that extends in a first direction on a substrate, a plurality of channel layers spaced apart from each other in a vertical direction perpendicular to an upper surface of the substrate on the active region, a gate structure including a gate electrode that intersects the active region and the plurality of channel layers and extends around ones of the plurality of channel layers, a gate spacer on side surfaces of the gate electrode, and a gate capping layer on the gate electrode and the gate spacer, and extends in a second direction, wherein the gate capping layer of the gate structure has, in an upper region, a first region having a substantially flat upper surface and a second region on at least a first side of the first region and having a rounded upper surface, a source/drain region on the active region on a first side of the gate structure and in contact with the plurality of channel layers, a contact structure on the source/drain region on the first side of the gate structure, electrically connected to the source/drain region, and extends in the second direction, and a stopper layer on the gate structure and the contact structure, wherein the stopper layer includes a first portion on the first region of the gate capping layer, a second portion on an upper surface of the contact structure, and a third portion that extends downwardly along the second region of the gate capping layer on at least one side of the first portion and electrically connected to a first side of the second portion.

### BRIEF DESCRIPTION OF DRAWINGS

The above and other aspects, features, and advantages in the example embodiments will be more clearly understood from the following detailed description, taken in combination with the accompanying drawings, in which:

FIG. 1 is a plan diagram illustrating a semiconductor device according to example embodiments of the present disclosure;

FIG. 2 is a cross-sectional diagram illustrating a semiconductor device according to example embodiments of the present disclosure;

FIG. 3 is an enlarged diagram illustrating a portion of the semiconductor device illustrated in FIG. 2;

FIG. 4 is an enlarged diagram illustrating a portion of the semiconductor according to example embodiments of the present disclosure; and

FIGS. 5 to 17 are vertical cross-sectional diagrams illustrating processes of a method of manufacturing a semiconductor device in order according to example embodiments of the present disclosure.

### DETAILED DESCRIPTION

Hereinafter, embodiments in the example embodiments will be described as follows with reference to the accompanying drawings.

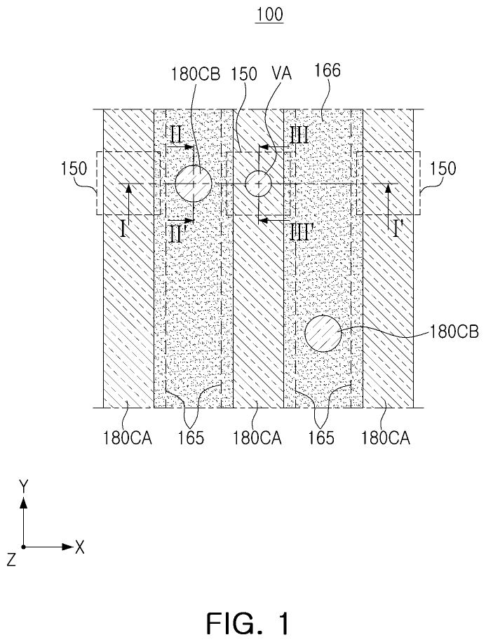

FIG. 1 is a plan diagram illustrating a semiconductor device according to example embodiments.

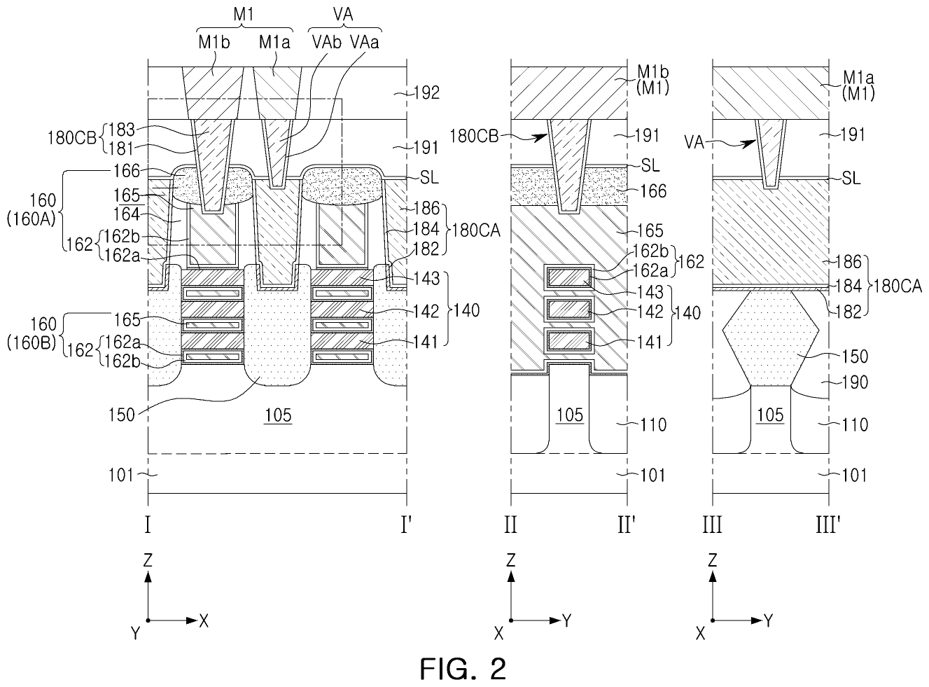

FIG. 2 is a cross-sectional diagram illustrating a semiconductor device according to example embodiments, taken along lines I-I′, II-II′, and III-III′. For ease of description, only the main components of the semiconductor device are illustrated in FIGS. 1 and 2.

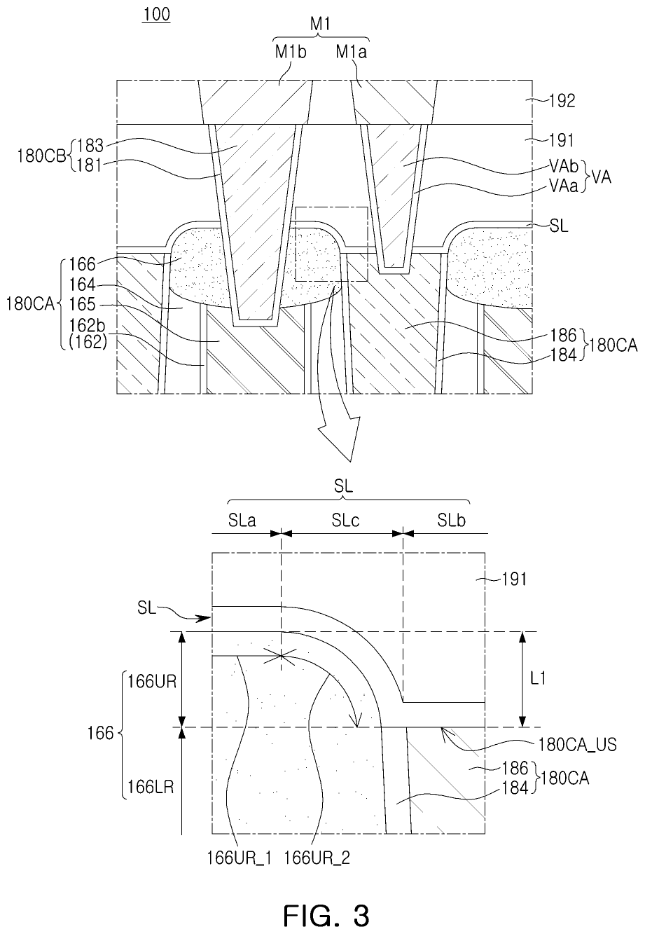

FIG. 3 is an enlarged diagram illustrating a portion of the semiconductor device illustrated in FIG. 2, illustrating region “A” in the cross-sectional diagram taken along line I-I′ in FIG. 2.

Referring to FIGS. 1 to 3, a semiconductor device 100 may include a substrate 101, an active region 105 on the substrate 101, a channel structure 140 including a plurality of channel layers 141, 142, and 143 vertically disposed and spaced apart from each other on the active region 105, a source/drain region 150 in contact with the plurality of channel layers 141, 142, and 143, a gate structure 160 extending by intersecting the active region 105, a contact plug 180CA connected to the source/drain region 150, an interconnection via structure VA connected to the contact plug 180CA, and a gate contact plug 180CB connected to the gate electrode 165. The semiconductor device 100 may further include device isolation layers 110, a stopper layer SL, and a plurality of interlayer insulating layers 190, 191, and 192. According to example embodiments, the semiconductor device 100 may further include interconnection line structures M1. The gate structure 160 may include gate spacer layers 164, first and second gate dielectric layers 162a and 162b, a gate electrode 165, and a gate capping layer 166.

In the semiconductor device 100, the active region 105 may have a fin structure, and the gate electrode layer 163 may be disposed between the active region 105 and the channel structure 140, between ones of the plurality of channel layers 141, 142, and 143 of the channel structures 140, and in an upper portion of the channel structure 140. Accordingly, the semiconductor device 100 may include a gate-all-around type field effect transistor, that is, a multi bridge channel FET™ (MBCFET™), by the channel structure 140, the source/drain region 150, and the gate structure 160. The transistors may be, for example, NMOS transistors.

The substrate 101 may have an upper surface extending in the X-direction and Y-direction. The substrate 101 may include a semiconductor material, such as a group IV semiconductor, a group III-V compound semiconductor, or a group II-VI compound semiconductor. For example, a group IV semiconductors may include silicon, germanium, or silicon-germanium. The substrate 101 may be provided as a bulk wafer, an epitaxial layer, a silicon on insulator (SOI) layer, or a semiconductor on insulator (SeOI) layer.

The device isolation layer 110 may define the active region 105 in the substrate 101. The device isolation layer 110 may be formed, for example, by a shallow trench isolation (STI) process. In example embodiments, the device isolation layer 110 may further include a region having a step difference below the substrate 101 and extending deeper. The device isolation layer 110 may partially expose an upper portion of the active region 105. In example embodiments, the device isolation layer 110 may have a curved upper surface having a higher level or height toward or adjacent the active region 105. The device isolation layer 110 may be formed of an insulating material. The device isolation layer 110 may be, for example, oxide, nitride, or a combination thereof.

The active region 105 may be defined by the device isolation layer 110 in the substrate 101 and may extend in the first direction, for example, the X-direction. The active region 105 may have a structure protruding from or extending from the substrate 101. An upper end of the active region 105 may be disposed to protrude at a predetermined level or height from an upper surface of the device isolation layer 110 with respect to the substrate 101. The active region 105 may include a portion of the substrate 101 or may include an epitaxial layer grown from the substrate 101. However, the active region 105 on the substrate 101 may be partially recessed on both sides of the gate structure 160, and the source/drain region 150 may be disposed on the recessed active region 105. The active region 105 may include impurities or may include doped regions including impurities.

The channel structure 140 may include first to third channel layers 141, 142, and 143, two or more channel layers spaced apart from each other in a direction perpendicular to an upper surface of active region 105 on the active region 105, for example, in the Z-direction. The first to third channel layers 141, 142, and 143 may be electrically and/or physically connected to the source/drain region 150 and may be spaced apart from an upper surface of the active region 105. The first to third channel layers 141, 142, and 143 may have a width the same as or similar to that of the active region 105 in the Y-direction, and may have a width the same as or similar to that of the gate structure 160 in the X-direction. In example embodiments, the first to third channel layers 141, 142, and 143 may have a reduced width such that side surfaces may be disposed on the lower portion of the gate structure 160 in the X-direction. Accordingly, the area in contact with the source/drain region 150 and the plurality of channel layers 141, 142, and 143 may decrease.

The first to third channel layers 141, 142, and 143 may be formed of a semiconductor material and may include silicon (Si), for example. In some embodiments, the first to third channel layers 141, 142, and 143 may be formed of the same material as that of the substrate 101. The number of the channel layers 141, 142, and 143 included in the channel structure 140 and the shape thereof may be varied in example embodiments. For example, in example embodiments, the channel structure 140 may further include a channel layer disposed on an upper surface of the active region 105.

The source/drain region 150 may be disposed on the active region 105 on both sides of the plurality of channel layers 141, 142, and 143. The source/drain region 150 may be provided as a source region or a drain region of a transistor. The source/drain region 150 may be partially recessed into an upper portion of the active region 105, and in example embodiments, presence of the recess and a depth of the recess may be varied. The source/drain region 150 may include epitaxial layers disposed along a side surface of each of the plurality of channel layers 141, 142, and 143. The source/drain region 150 may be configured as a semiconductor layer including silicon (Si) and/or germanium (SiGe). The source/drain region 150 may include impurities having different types and/or concentrations. For example, the source/drain region 150 may include n-type doped silicon (Si) and/or p-type doped silicon germanium (SiGe). In example embodiments, the source/drain region 150 may include a plurality of regions including different concentrations of elements and/or doping elements. A cross-sectional surface of the source/drain region 150 in the Y-direction may have a circular, oval, pentagonal, hexagonal, or similar shape. However, in example embodiments, the source/drain region 150 may have various shapes, for example, one of a polygonal, circular, and/or rectangular shapes.

The gate structure 160 may intersect the active region 105, and the plurality of channel layers 141, 142, and 143 and may extend in one direction, for example, the Y-direction in an upper portion of the active region 105 and the plurality of channel layers 141, 142, and 143. A channel region of transistors may be formed in the active region 105 and/or the plurality of channel layers 141, 142, and 143 intersecting the gate structure 160. The gate structure 160 may include an upper portion 160A disposed on an uppermost channel layer among the plurality of channel layers 141, 142, and 143 and a lower portion 160B disposed below ones of the plurality of channel layers 141, 142, and 143. According to example embodiments, a lowermost portion of the source/drain regions 150 may be disposed on a level lower than a level of a lowermost portion of the lower portions 160B of the gate structure 160. The gate structure 160 may include a gate electrode 165, first and second gate dielectric layers 162a and 162b between the gate electrode 165 and the plurality of channel layers 141, 142, and 143, and gate spacer layers 164 on side surfaces of the gate electrode 165, and a gate capping layer 166 on an upper surface of the gate electrode 165.

The first and second gate dielectric layers 162a and 162b may be disposed between the active region 105 and the gate electrode 165 and the plurality of channel layers 141, 142, and 143 and the gate electrode 165, and may be disposed to cover or overlap at least a portion of surfaces of the gate electrode 165. For example, in the upper portion 160A of the gate structure 160, the first gate dielectric layer 162a may be disposed on a lower surface of the second gate dielectric layer 162b, which is on a lower surface of the gate electrode 165. The second gate dielectric layer 162b may be disposed to surround the entirety of surfaces other than an uppermost surface of the gate electrode 165 in cross-sectional view. The first and second gate dielectric layers 162a and 162b may extend to a region between the gate electrode 165 and the gate spacer layers 164, but example embodiments thereof are not limited thereto. The first and second gate dielectric layers 162a and 162b may have the same thickness or different thicknesses.

The first and second gate dielectric layers 162a and 162b may be formed of the same material or may include different materials. The first and second gate dielectric layers 162a, 162b may include oxide, nitride, or a high-κ material. The high-material may include, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and/or praseodymium oxide (Pr₂O₃).

The gate electrode 165 may partially or fully fill a space between an upper portion of the active region 105 and the plurality of channel layers 141, 142, and 143, and may extend to an upper portion of the plurality of channel layers 141, 142, and 143. The gate electrode 165 may be spaced apart from the plurality of channel layers 141, 142, and 143 by the first and second gate dielectric layers 162a and 162b. The gate electrode 165 may include a conductive material. For example, the gate electrode 165 may include metal nitride such as titanium nitride (TiN), tantalum nitride (TaN), or tungsten nitride (WN), and/or a metal material such as aluminum (Al), tungsten (W), or molybdenum (Mo) or a semiconductor material such as doped polysilicon.

The gate electrode 165 may include two or more multiple layers. The gate spacer layers 164 may be disposed on both side surfaces of the gate electrode 165. The gate spacer layers 164 may insulate the source/drain region 150 from the gate electrode 165. In example embodiments, the gate spacer layers 164 may have a multilayer structure. A width of each of the gate spacer layers 164 in a first direction, for example, a horizontal width in the X-direction, may vary depending on a depth in a third direction, for example, a level in the Z-direction. For example, the horizontal width of each of the gate spacer layers 164 may increase from an upper surface of the gate spacer layers 164 to a lower surface of the gate spacer layers 164. In other words, a thickness of each of the gate spacer layers 164 in the X-direction may increase toward the upper surface of the substrate 101. The gate spacer layers 164 may include at least one of oxide, nitride, oxynitride and/or a low-K dielectric.

The gate capping layer 166 may be disposed on an upper portion of the gate electrode 165. The gate capping layer 166 may extend in the second direction, for example, the Y-direction, along an upper surface of the gate electrode 165. A lower surface of the gate capping layer 166 may be in contact with an upper surface of the gate electrode 165 and upper surfaces of the gate spacer layers 164.

A width of the gate capping layer 166 in the first direction, for example, a horizontal width in the X-direction, may vary depending on a depth in the third direction, for example, a level or height in the Z-direction. For example, the horizontal width of the gate capping layer 166 may increase from an upper surface of the gate capping layer 166 to a lower surface of the gate capping layer 166. In other words, the thickness of the gate capping layer 166 in the X-direction may increase toward the upper surface of the substrate 101.

The gate capping layer 166 may include an upper region 166UR and a lower region 166LR. The upper region 166UR of the gate capping layer may be defined as having a first region 166UR_1 and a second region 166UR_2 (or “edge region”) disposed on at least one side of the first region 166UR_1. The first region 166UR_1 may have a region having a substantially flat upper surface, and the second region 166UR_2 may be defined as having an upper surface having an upward curved shape. For example, the second region 166UR_2 may be configured to have a rounded shape upper surface. The upper surface of the second region 166UR_2 may be a portion physically connecting an upper surface of first region 166UR_1 to a side surface of the lower region 166LR.

The gate capping layer 166 may be formed of oxide, nitride, and oxynitride, and may specifically include at least one of SiO, SiN, SiCN, SiOC, SiON, and/or SiOCN.

The first interlayer insulating layer 190 may cover or overlap the source/drain region 150 and the device isolation layer 110. The interlayer insulating layer 190 may include, for example, at least one of oxide, nitride, oxynitride and/or a low-K dielectric.

The contact structures 180CA may be spaced apart from the gate structures 160 in the first direction, for example, the X-direction, and may extend in the second direction, for example, the Y-direction, on the source/drain region 150 (see FIG. 1). The contact structures 180CA may be in contact with the source/drain region 150 between the gate structures 160 and may apply an electrical signal to the source/drain region 150.

The contact structures 180CA may include a metal-semiconductor compound layer 182 disposed on a lower end, a barrier layer 184 disposed along sidewalls, and a plug conductive layer 186. The metal-semiconductor compound layer 182 may be, for example, a metal silicide layer. The barrier layer 184 may include a metal nitride, such as titanium nitride (TiN), tantalum nitride (TaN), or tungsten nitride (WN). The plug conductive layer 186 may include a metal material such as aluminum (Al), tungsten (W), or molybdenum (Mo). In example embodiments, each of the contact structures 180CA may penetrate or extend into at least a portion of the source/drain region 150. In example embodiments, the number of the contact structures 180CA and the dispositional form thereof may be varied.

The contact structures 180CA may have an inclined side surface (i.e., at an angle) of which a width of a lower portion may be narrower than a width of an upper portion depending on an aspect ratio, but example embodiments thereof are not limited thereto. The contact structures 180CA may be recessed into the source/drain region 150 to a predetermined depth. The upper surface 180CA_US of the contact structures may be substantially flat. The upper surface 180CA_US of the contact structures may be disposed on a level lower or height than a level or height of the upper surface of the gate capping layer 166. A level or height difference between the upper surface 180CA_US of the contact structures and the upper surface of the gate capping layer 166 may be defined as a first gap L1. The first gap L1 may be 10 nm or less, for example, 3 nm to 7 nm, or 3 nm to 5 nm, or 3.5 nm to 4 nm.

The stopper layer SL may cover or overlap the gate structures 160 and the contact structures 180CA. The stopper layer SL may be defined as including a plurality of portions, for example, a first stopper layer portion SLa, a second stopper layer portion SLb, and a third stopper layer portion SLc.

The first stopper layer portion SLa may be defined as a portion covering or overlapping an upper surface of the first region 166UR_1 among upper regions of the gate capping layer. The second stopper layer portion SLb may be defined as a portion covering or overlapping an upper surface 180CA_US of the contact structures. The third stopper layer portion SLc may be defined as a portion covering or overlapping an upper surface of the second region 166UR_2 among upper regions of the gate capping layer. The third stopper layer portion SLc may be disposed between the first stopper layer portion SLa and the second stopper layer portion SLb, and may be a component connecting the first stopper layer portion SLa to the second stopper layer portion SLb.

A lower surface of the second stopper layer portion SLb may be disposed on a level or height lower than a level or height of a lower surface of the first stopper layer portion SLa. A level or height difference between the lower surface of the second stopper layer portion SLb and the lower surface of the first stopper layer portion SLa may be defined as a first gap L1. Here, the first gap L1 may be the same as the first gap L1 described in the above example in which a level difference between the upper surface of the contact structures 180CA_US and the upper surface of the gate capping layer 166.

At least a portion of the third stopper layer portion SLc may include an inclined portion, inclined with respect to the upper surface 180CA_US of the contact structure. In other words, the third stopper layer portion SLc may not include a flat upper surface and/or a lower surface, differently from the first stopper layer portion SLa and the second stopper layer portion SLb. A shape of the third stopper layer portion SLc may be similar to a shape of an upper surface of the second region 166UR_2 of an upper region of the gate capping layer. For example, in terms of cross-section, the third stopper layer portion SLc may have an upwardly curved shape.

Specifically, each of a portion of the third stopper layer portion SLc in contact with a surface of the gate capping layer 166 and a portion of the third stopper layer portion SLc in contact with the first interlayer insulating layer 191 may have a rounded shape.

For example, the stopper layer SL may include at least one of silicon nitride and/or silicon oxynitride.

The second interlayer insulating layer 192 may be disposed to cover or overlap the stopper layer SL. The first interlayer insulating layer 191 may include, for example, at least one of oxide, nitride, oxynitride and/or a low-K dielectric.

The gate contact structures 180CB may penetrate or extend into at least a portion of a first interlayer insulating layer 191, a stopper layer SL, and a gate capping layer 166, may be in contact with the gate electrode 165, and may apply an electrical signal to the gate electrode 165. The gate contact structures 180CB may penetrate or extend into the first stopper layer portion SLa between the third stopper layer portions SLc of the stopper layer SL. By the third stopper layer portions SLc forming a step difference of the stopper layer SL, shorts occurring between the gate contact structures 180CB and the contact structures 180CA may be reduced or prevented.

The gate contact structures 180CB may include a barrier layer 181 disposed along sidewalls, and a plug conductive layer 183. The barrier layer 181 may include a metal nitride, such as titanium nitride (TiN), tantalum nitride (TaN), or tungsten nitride (WN). The plug conductive layer 183 may include a metal material such as aluminum (Al), tungsten (W), or molybdenum (Mo). In example embodiments, the gate contact structure 180CB may be disposed to penetrate or extend into at least a portion of the gate electrode 165. In example embodiments, the number of the conductive layers included in the gate contact structure 180CB and the dispositional form thereof may be varied.

The interconnection via structure VA may penetrate or extend into at least a portion of the first interlayer insulating layer 191 and the stopper layer SL and may be in contact with the contact structures 180CA, and may apply an electrical signal to the contact structures 180CA.

The interconnection via structure VA may include a barrier layer VAa disposed along sidewalls, and a via plug conductive layer VAb. The barrier layer VAa may include metal nitride, such as titanium nitride (TiN), tantalum nitride (TaN), or tungsten nitride (WN). The via plug conductive layer VAb may include a metal material such as aluminum (Al), tungsten (W), or molybdenum (Mo). In example embodiments, the interconnection via structure VA may be disposed to penetrate or extend into at least a portion of the contact structures 180CA. In example embodiments, the number of the conductive layers included in the interconnection via structure VA and the dispositional form thereof may be varied.

The third interlayer insulating layer 192 may be disposed to cover or overlap the gate contact structures 180CB and the interconnection via structure VA on the first interlayer insulating layer 191. For example, the second interlayer insulating layer 192 may include at least one of oxide, nitride, oxynitride and/or a low-κ dielectric.

The interconnection line structure M1 may include a first metal interconnection M1a and a second metal interconnection M1b. The first metal interconnection M1a may be electrically connected to the source/drain region 150 through the interconnection via structure VA and the contact structure 180CA, and the second metal interconnection M1b may be electrically connected to the gate electrode 165 through the gate contact structure 180CB. A side surface portion of the interconnection line structure M1 may be surrounded by the second interlayer insulating layer 192. If desired, interconnection line structures, interconnection via structures, and interlayer insulating layers may be further disposed on the interconnection line structure M1 and the second interlayer insulating layer 192 (not illustrated).

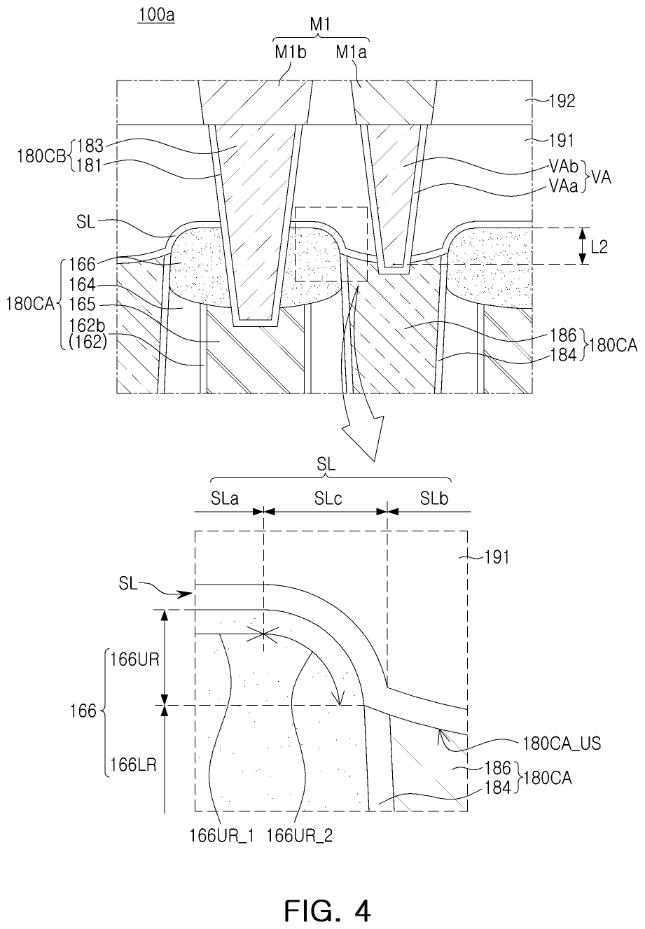

FIG. 4 is an enlarged diagram illustrating a portion of the semiconductor according to example embodiments.

Referring to FIG. 4, the semiconductor device 100a may be the same or similar to those described with reference to FIGS. 1 to 3 other than the configuration in which an upper surface 180CA_US of contact structures has a curved shape.

Referring to FIG. 4, the upper surface 180CA_US of the contact structures may have a downwardly curved shape. For example, the upper surface 180CA_US of the contact structures may have a downwardly curved shape in terms of cross-section.

Accordingly, the shape of the second stopper layer portion SLb of the stopper layer SL, disposed on the upper surface 180CA_US of the contact structures, may also be similar to the shape of the upper surface 180CA_US of the contact structures. Specifically, in terms of cross-section, the second stopper layer portion SLb may have a downwardly curved shape, for example. In this case, a level or height difference between a lower surface of the first stopper layer portion SLa and a lowermost surface of the second stopper layer portion SLb may be greater than the first gap L1 described with reference to FIGS. 1 to 3. Here, the lowermost surface of the second stopper layer portion SLb may be defined as a lower surface of a portion formed in a central portion of an upper surface of the contact structures 180CA.

A level or height difference between a lower surface of the first stopper layer portion SLa and a lowermost surface of the second stopper layer portion SLb may be defined as a second gap L2, and the second gap L2 may be 11 nm or less, for example, 4 nm to 8 nm, or 3.5 nm to 6 nm, or 4 nm to 4.5 nm.

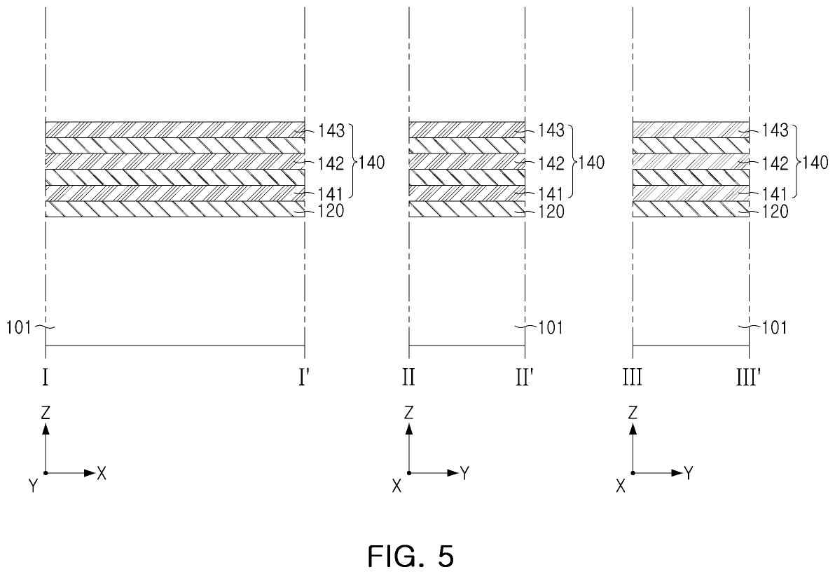

FIGS. 5 to 17 are vertical cross-sectional diagrams illustrating processes of a method of manufacturing a semiconductor device in order according to example embodiments.

Referring to FIG. 5, sacrificial layers 120 and a plurality of channel layers 141, 142, and 143 may be alternately stacked on the active region 105.

The sacrificial layers 120 may be replaced with first and second gate dielectric layers 162a and 162b and a gate electrode 165 as illustrated in FIG. 2 through a subsequent process. The sacrificial layers 120 may be formed of a material having etch selectivity for the channel layers 141, 142, and 143. The channel layers 141, 142, and 143 may include a material different from that of the sacrificial layers 120. In example embodiments, the channel layers 141, 142, and 142 may include silicon (Si), and the sacrificial layers 120 may include silicon germanium (SiGe).

The sacrificial layers 120 and the channel layers 141, 142, and 143 may be formed by performing an epitaxial growth process using a substrate 101 as a seed. Each of the sacrificial layers 120 and the channel layers 141, 142, and 143 may have a thickness ranging from about 1 Å to 100 nm. The number of layers of the channel layers 141, 142, and 143 alternately stacked with the sacrificial layer 120 may be varied in example embodiments.

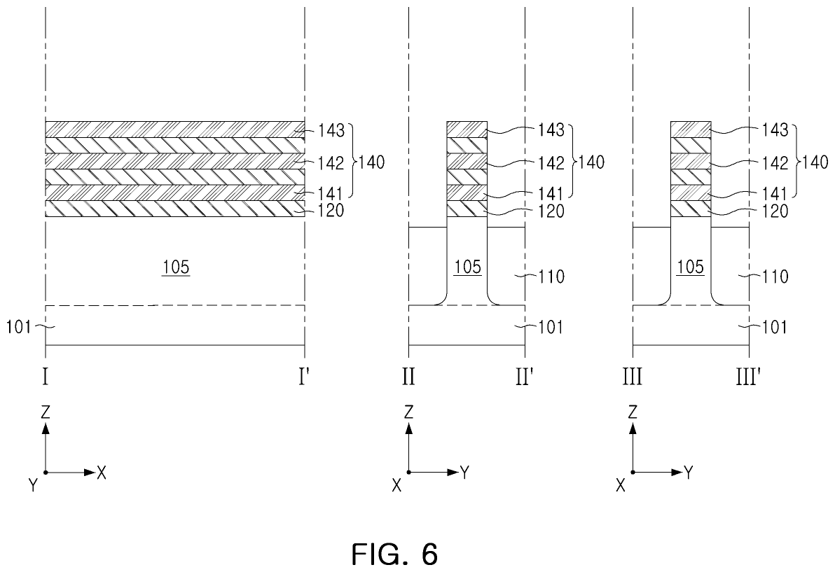

Referring to FIG. 6, active structures may be formed by removing a portion of the stacked structure of the sacrificial layers 120 and the channel layers 141, 142, and 143 and the substrate 101.

The active structure may include the sacrificial layers 120 and the plurality of channel layers 141, 142, and 143 alternately stacked with each other, and may further include an active region 105 formed to protrude to an upper surface of the substrate 101 by removing a portion of the substrate 101. The active structures may be formed in the form of a line extending in one direction, for example, the X-direction, and may be spaced apart from each other in the Y-direction. Depending on an aspect ratio, the active region 105 may have an inclined shape such that a width thereof may increase downwardly towards the substrate 101.

By partially or fully filling an insulating material in a region from which a portion of the substrate 101 has been removed, and recessing the active region 105 to protrude, device isolation layers 110 may be formed. An upper surface of the device isolation layers 110 may be formed on a level or height lower than a level or height of an upper surface of the active region 105.

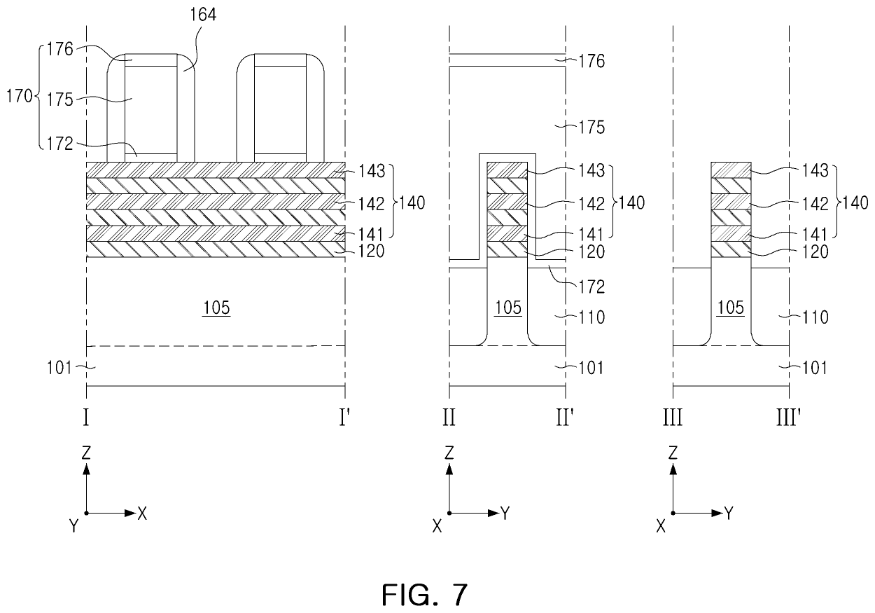

Referring to FIG. 7, sacrificial gate structures 170 and gate spacer layers 164 may be formed on the active structures.

The sacrificial gate structures 170 may be configured as sacrificial structure formed in a region of an upper portion of the plurality of channel layers 141, 142, and 143, in which the first and second gate dielectric layers 162a and 162b and the gate electrode 165 are disposed. The sacrificial gate structures 170 may include first and second sacrificial gate layers 172 and 175, and a mask pattern layer 176 stacked in order. The first and second sacrificial gate layers 172 and 175 may be patterned using the mask pattern layer 176. The first and second sacrificial gate layers 172 and 175 may be an insulating layer and a conductive layer, respectively. For example, the first sacrificial gate layer 172 may include silicon oxide, and the second sacrificial gate layer 175 may include polysilicon. The mask pattern layer 176 may include silicon nitride. The sacrificial gate structures 170 may have a line shape intersecting the active structures and extending in one direction. For example, the sacrificial gate structures 170 may extend in the Y-direction and may be spaced apart from each other in the X-direction.

The gate spacer layers 164 may be formed on both sidewalls of the sacrificial gate structures 170. The gate spacer layers 164 may be formed by forming a film having a uniform thickness along upper surfaces and side surfaces of the sacrificial gate structures 170 and the active structures, and performing anisotropically etching. The gate spacer layers 164 may be formed of a low-κ material and may include, for example, at least one of SiO, SiN, SiCN, SiOC, SiON, and/or SiOCN.

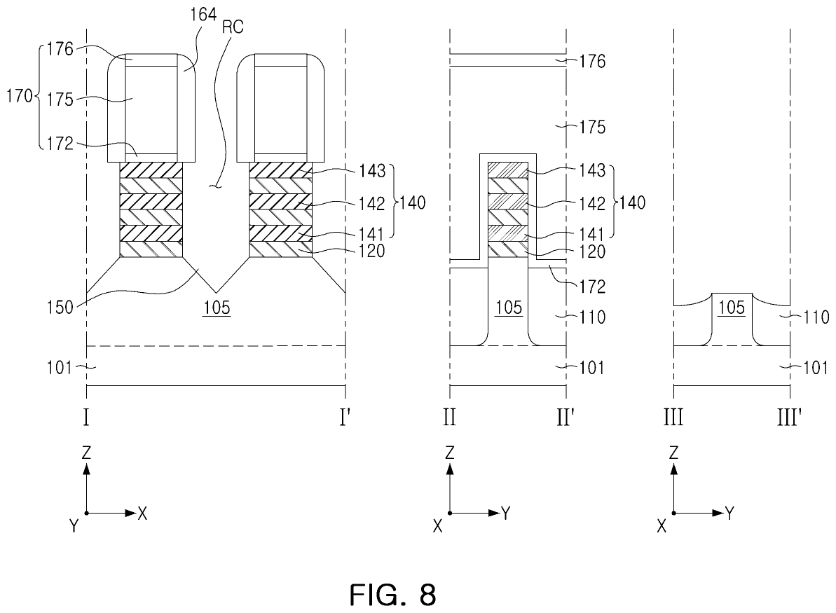

Referring to FIG. 8, by removing a portion of the exposed sacrificial layers 120 and the plurality of channel layers 141, 142, and 143 between the sacrificial gate structures 170, a recess region RC may be formed, and the plurality of channel layers 141, portions of 142 and 143 and the active region 105 may be removed.

The recess region RC may be formed by removing a portion of the exposed sacrificial layers 120 and the plurality of channel layers 141, 142, and 143 using the sacrificial gate structures 170 and the gate spacer layers 164 as a mask. For example, the recess process may be formed by applying a dry etching process and a wet etching process in sequence. First, the recess region RC may be formed in a vertical direction through a dry etching process. Thereafter, the recess region RC may be formed in a horizontal direction through a wet etching process. Accordingly, the plurality of channel layers 141, 142, and 143 may have a limited length in the X-direction.

The plurality of channel layers 141, 142, and 143 and the active region 105 may be etched using crystallographic anisotropic etching. In crystallographic anisotropic etching by wet etching, KOH, NaOH, NH4OH, or tetramethylammonium hydroxide (TMAH) may be used as an etchant. By using crystallographic anisotropic etching, the plurality of channel layers 141, 142, and 143 may be etched at different etching rates depending on crystal orientations of the plurality of channel layers 141, 142, and 143 and the substrate 101. Accordingly, at least a portion of external side surfaces of the plurality of channel layers 141, 142, and 143 and an upper surface of the active region 105 may have a 111 crystal orientation, and the plurality of channel layers 141, 142, and 143 may have a pointed sigma shape toward a central portion. The specific shapes of the side surfaces of the plurality of channel layers 141, 142, and 143 and an upper portion of the active region 105 is not limited to the examples illustrated in FIG. 8.

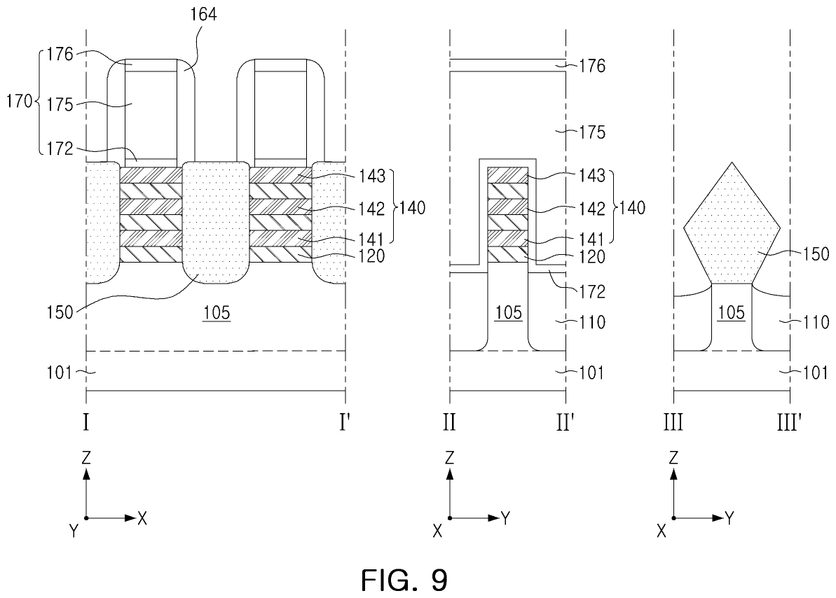

Referring to FIG. 9, an epitaxial layer of the source/drain region 150 may be formed to fill the recess region RC.

The source/drain region 150 may be formed by an epitaxial growth process. The source/drain region 150 may be formed by repeating epitaxial growth and etching processes, and may extend to be in contact with the lower portion 160B of the plurality of channel layers 141, 142, and 143 and the gate structures 160. The source/drain region 150 may include impurities due to in-situ doping. Upper surfaces of the source/drain regions 150 may be disposed on a level or height substantially the same as or higher than a level or height of a lower surface of an upper portion 160A of the gate structures 160, but example embodiments thereof are not limited thereto.

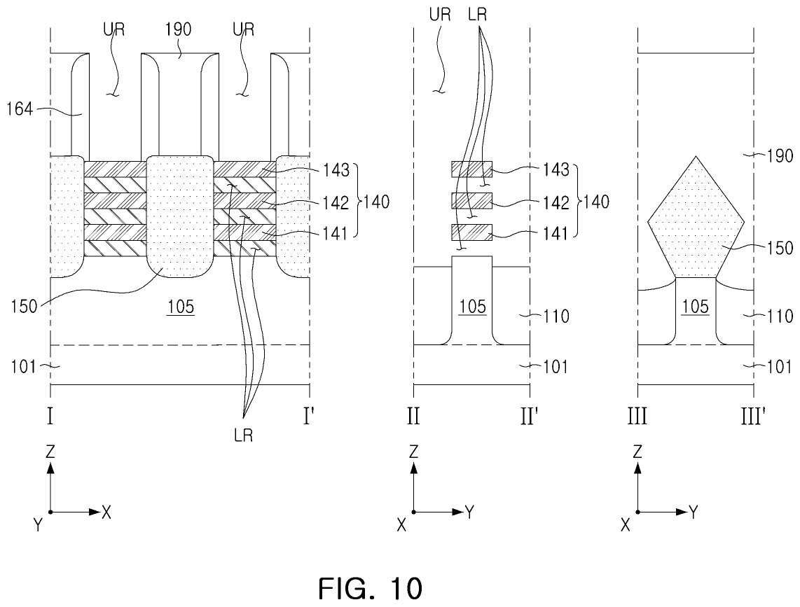

Referring to FIG. 10, an interlayer insulating layer 190 may be formed, and the sacrificial layers 120 and the sacrificial gate structures 170 may be removed.

The interlayer insulating layer 190 may be formed by forming an insulating film covering or overlapping the sacrificial gate structures 170 and the source/drain region 150 and performing a planarization process.

The sacrificial layers 120 and the sacrificial gate structures 170 may be selectively removed with respect to the gate spacer layers 164, the interlayer insulating layer 190, and the plurality of channel layers 141, 142, and 143. First, upper gap regions UR may be formed by removing the sacrificial gate structures 170, and lower gap regions LR may be formed by removing the sacrificial layers 120 exposed through the upper gap regions UR. For example, when the sacrificial layers 120 include silicon germanium (SiGe) and the plurality of channel layers 141, 142, and 143 include silicon (Si), the sacrificial layers 120 may be selectively removed by performing a wet etching process using peracetic acid and/or solution (NH₄OH:H₂O₂:H₂O=1:1:5) used in a standard clean-1 (SC1) cleaning process as an etchant.

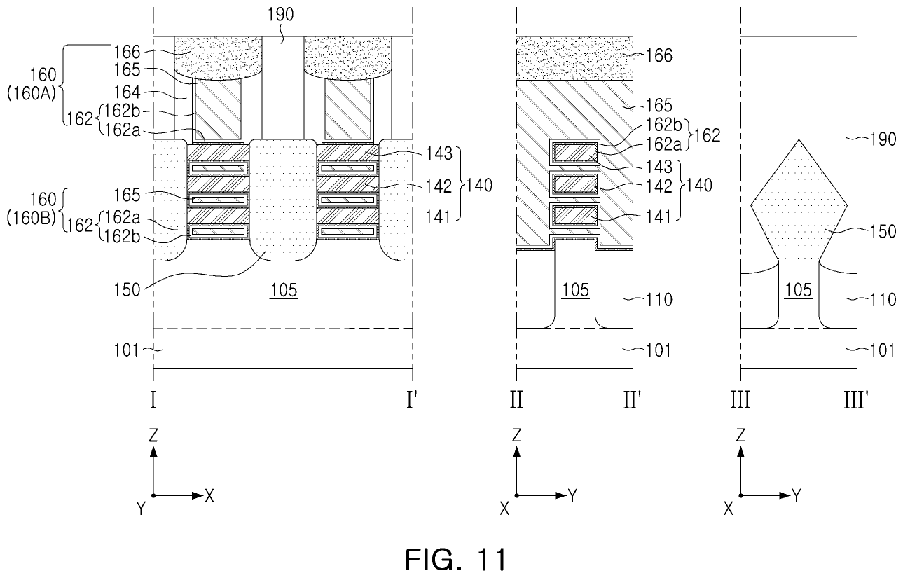

Referring to FIG. 11, the gate structure 160 may be formed in the upper gap regions UR and the lower gap regions LR.

The first and second gate dielectric layers 162a and 162b may be formed to conformally cover or overlap internal surfaces of the upper gap regions UR and the lower gap regions LR. The gate electrode 165 may be formed to partially or completely fill the upper gap regions UR and the lower gap regions LR. The gate electrode 165 and the gate spacer layers 164 may be removed from the upper gap regions UR to a predetermined depth downwardly towards the substrate 101. In the upper gap regions UR, the gate capping layer 166 may be formed in a region from which the gate electrode 165 and the gate spacer layers 164 have been removed. Accordingly, the gate structure 160 including the first and second gate dielectric layers 162a and 162b, the gate electrode 165, and the gate spacer layers 164, and the gate capping layer 166 may be formed.

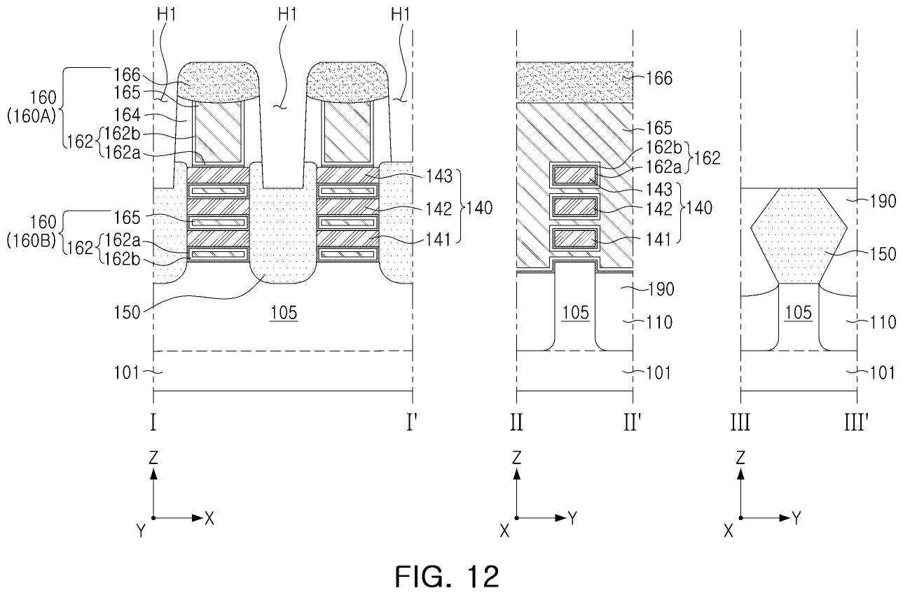

Referring to FIG. 12, a plurality of contact holes H1, at least a portion of which penetrates or extends into the source/drain region 150, may be formed between the gate structures 160.

The plurality of contact holes H1 may be formed by a self-aligned contact (SAC) etching process (hereinafter, referred to as a SAC process). The self-aligned contact etching process may be performed using a difference in etch selectivity between the gate capping layer 166 and the interlayer insulating layer 190. Accordingly, the gate capping layer 166 and the interlayer insulating layer 190 may include different materials. In example embodiments, the gate capping layer 166 may include silicon nitride, and the interlayer insulating layer 190 may include silicon oxide.

In each of the plurality of contact holes H1 formed by the SAC process, a width of an upper region may be greater than a width of a lower region. Accordingly, at least a portion of an edge portion 166UR_2 of an upper region of the gate capping layer 166 may be etched and may have a rounded shape (see FIGS. 2 and 3).

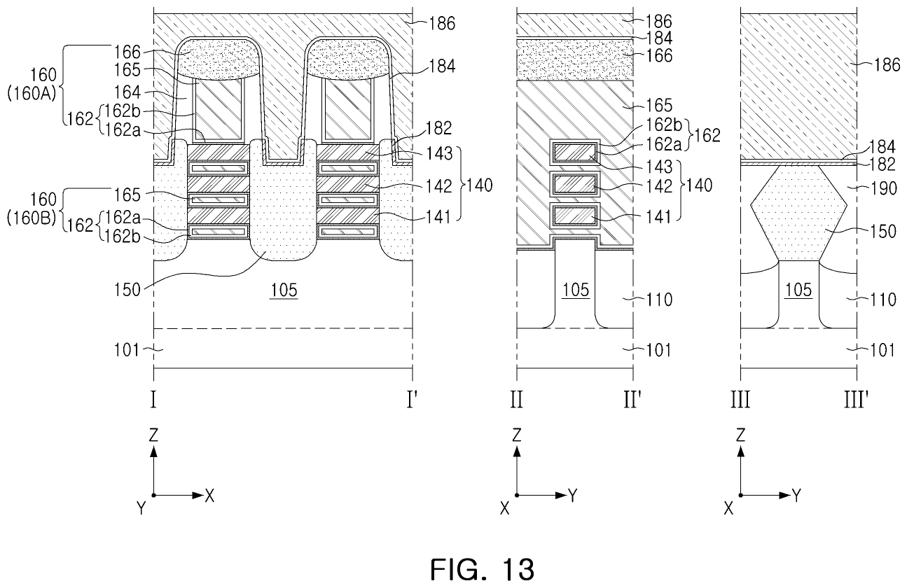

Referring to FIG. 13, a metal-semiconductor compound layer 182, a barrier layer 184, and a plug conductive layer 186 may be formed in order in the plurality of contact holes H1.

Referring to FIG. 13, the metal-semiconductor compound layer 182 may be formed to conformally cover or overlap a surface of the source/drain region 150 on a lower end of the plurality of contact holes H1. The barrier layer 184 may be formed to cover or overlap a surface of the metal-semiconductor compound layer 182 and the gate structure 160. Thereafter, the plug conductive layer 186 extending in the first direction (the X-direction) and the second direction (the Y-direction) may be formed on the barrier layer 184.

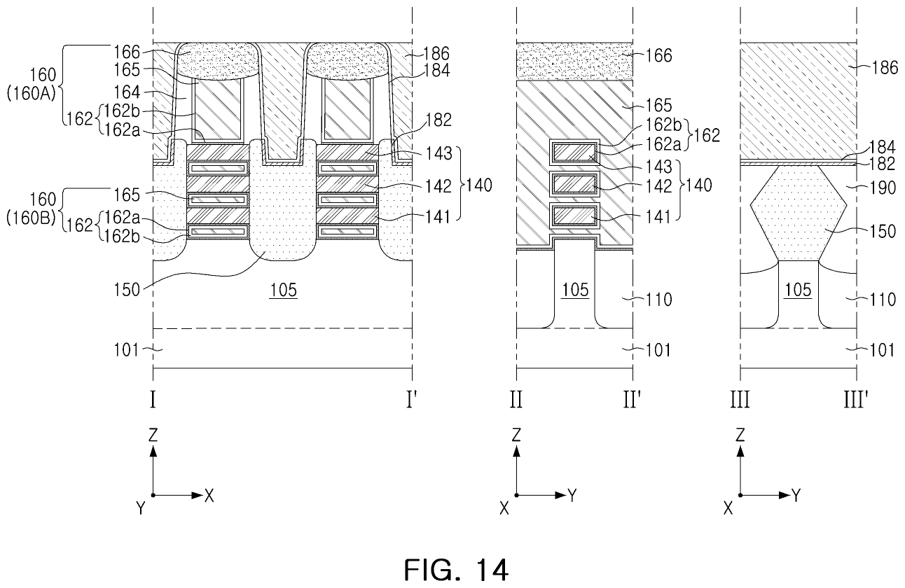

Referring to FIG. 14, by performing a planarization process, a plurality of plug conductive layers 186 spaced apart from each other in the first direction, for example, the X-direction may be formed.

By the planarization process, the plug conductive layer 186 and the barrier layer 184 of a portion vertically overlapping the gate structure 160 may be removed, and accordingly, an upper region of the gate capping layer 166 may be exposed.

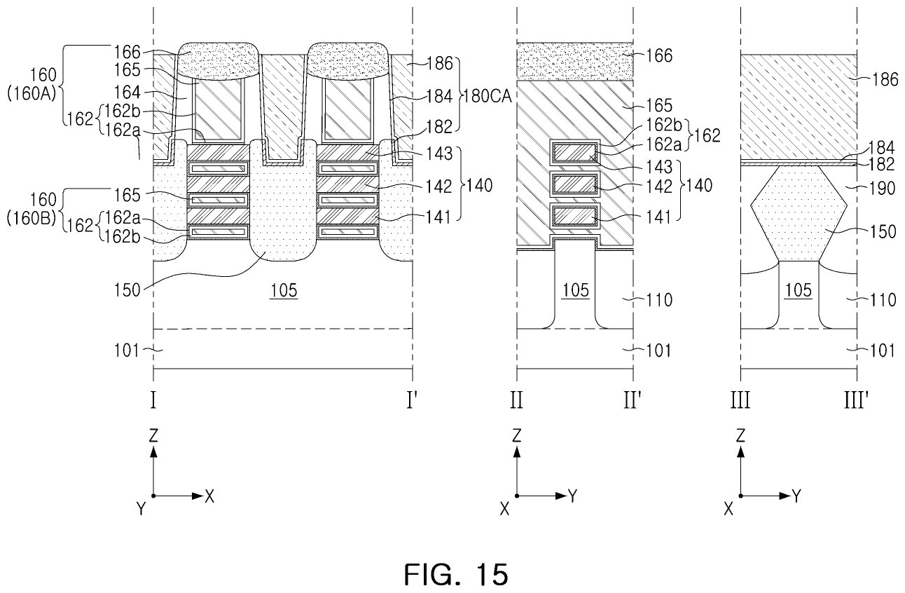

Referring to FIG. 15, the contact structure 180CA may be formed by performing an etchback process.

By the etchback process, a portion of an upper region of each of the plug conductive layers 186 and the barrier layer 184 may be removed. Accordingly, the plug conductive layers 186 and the barrier layer 184 may be formed, each of which has a substantially flat upper surface, but example embodiments thereof are not limited thereto. For example, referring to FIG. 4 together, the plug conductive layers 186 and the barrier layer 184 having upper surfaces having a downwardly curved shape may be formed.

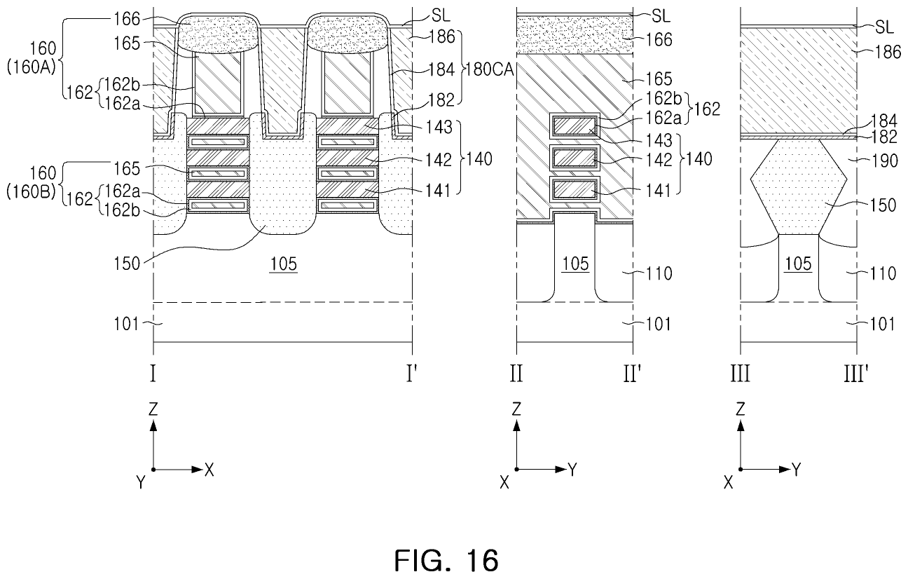

Referring to FIG. 16, a stopper layer SL may be formed on the gate structure 160 and the contact structure 180CA.

The stopper layer SL may be formed by depositing an insulating film on the gate structure 160 and the contact structure 180CA. The stopper layer SL may be formed to have substantially the same thickness on the gate structure 160 and the contact structure 180CA.

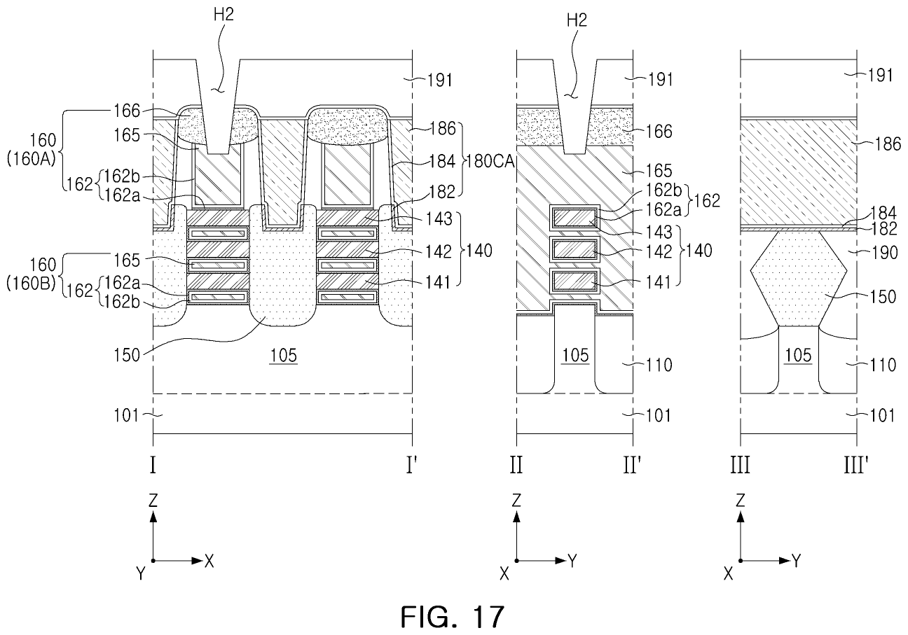

Referring to FIG. 17, an interlayer insulating layer 191 may be formed on the stopper layer SL, and a plurality of contact holes H2 penetrating or extending into at least a portion of the interlayer insulating layer 191 may be formed.

The interlayer insulating layer 191 may be formed by forming an insulating film covering or overlapping the stopper layer SL and performing a planarization process.

By patterning the interlayer insulating layer 191, the interlayer insulating layer 191, the stopper layer SL, and the gate capping layer 166 may be penetrated, and a plurality of contact holes H2 exposing a surface of the gate electrode 165 may be formed.

Thereafter, referring to FIGS. 2 and 3, a gate contact structure 180CB may be formed in the plurality of contact hole H2. The gate contact structure 180CB may include a barrier layer 181 formed along a sidewall, and a plug conductive layer 183 on the barrier layer 181.

After depositing a material forming the barrier layer 181 in the plurality of contact hole H2, the gate contact structure 180CB may be formed by partially or completely filling a conductive material therein.

Thereafter, although not illustrated, by patterning the interlayer insulating layer 191, the interlayer insulating layer 191 and the stopper layer SL may be penetrated, and a plurality of via holes exposing the contact structure 180CA may be formed. Interconnection via structures VA may be formed in the plurality of via holes (see FIGS. 2 and 3). Specifically, a material forming the barrier layer VAa may be deposited in the plurality of via holes, and a conductive material may be partially or completely filled therein, thereby forming the via plug conductive layer VAb. Thereafter, an interlayer insulating layer 192 covering or overlapping the gate contact structure 180CB and the interconnection via structures VA may be formed on the interlayer insulating layer 191. Thereafter, a plurality of open regions penetrating or extending into the interlayer insulating layer 192 and exposing each of the gate contact structure 180CB and the interconnection via structures VA may be formed, and the interconnection line structures M1 including the first metal interconnection M1a and the second metal interconnection M1b connected to the gate contact structure 180CB and the interconnection via structures VA, respectively, may be formed.

According to the aforementioned example embodiments, to prevent shorts between the contact structure connected to the source/drain region and the gate contact structure connected to the gate electrode, a semiconductor device including a stopper layer having a step difference may be provided.

Specifically, the semiconductor device in example embodiments may include a gate capping layer of which both ends of an upper region may have a rounded shape, a contact structure having an upper surface disposed on a level or height lower than an upper surface level or height of the gate capping layer, and a stopper layer disposed on the gate capping layer and the contact structure and having the step difference, such that shorts between the contact structure and the gate contact structure may be reduced or prevented, which may be implemented by a self-aligned contact etching process.

While the example embodiments have been illustrated and described above, it will be apparent to those skilled in the art that modifications and variations may be made without departing from the scope in the example embodiment as defined by the appended claims.

What is claimed is:

1. A semiconductor device, comprising:
an active region that extends in a first direction on a substrate;
a plurality of channel layers on the active region, wherein the plurality of channel layers are spaced apart from each other in a vertical direction perpendicular to an upper surface of the substrate;
a gate structure intersecting the active region and the plurality of channel layers, wherein the gate structure extends around ones of the plurality of channel layers and extends in a second direction, wherein the gate structure includes, in a region overlapping the plurality of channel layers in the vertical direction, lower portions below the plurality of channel layers, respectively, and an upper portion on an uppermost channel layer among the plurality of channel layers, and including a gate electrode and a gate capping layer on the gate electrode;
a source/drain region on the active region on at least a first side of the gate structure and in contact with the ones of the plurality of channel layers;
a contact structure on the source/drain region on at least the first side of the gate structure, wherein the contact structure is electrically connected to the source/drain region and extends in the second direction;
a stopper layer on the upper portion of the gate structure and on the contact structure, wherein the stopper layer comprises:
a first portion on the gate capping layer,
a second portion on the contact structure, and
at least one third portion on an edge portion of the gate capping layer and electrically connecting the first portion to the second portion; and
a gate contact structure that extends into the first portion of the stopper layer and the gate capping layer of the upper portion of the gate structure, and is electrically connected to the gate electrode of the gate structure,
wherein the at least one third portion has an inclined portion that is inclined with respect to an upper surface of the contact structure.

2. The semiconductor device of claim 1, further comprising:
a gate spacer on side surfaces of the gate electrode of the gate structure,
wherein a lower surface of the gate capping layer is in contact with an upper surface of the gate electrode and an upper surface of the gate spacer.

3. The semiconductor device of claim 2, wherein a width of the gate spacer increases from the lower surface of the gate capping layer towards the substrate.

4. The semiconductor device of claim 2, wherein a width of the gate capping layer increases toward the lower surface of the gate capping layer from an upper surface of the gate capping layer.

5. The semiconductor device of claim 1,
wherein a lower surface of the first portion of the stopper layer is in contact with an upper surface of the gate capping layer,
wherein a lower surface of the second portion of the stopper layer is in contact with an upper surface of the contact structure, and
wherein the lower surface of the second portion of the stopper layer is lower than the lower surface of the first portion of the stopper layer with respect to the substrate.

6. The semiconductor device of claim 5, wherein the upper surface of the contact structure and the lower surface of the second portion of the stopper layer have a curved shape that is curved towards the substrate.

7. The semiconductor device of claim 5, wherein the lower surface of the second portion of the stopper layer is 3 nm to 5 nm lower than the lower surface of the first portion of the stopper layer with respect to the substrate.

8. The semiconductor device of claim 1, wherein the edge portion of the gate capping layer has a rounded shape in cross-section.

9. The semiconductor device of claim 8, wherein the third portion of the stopper layer has a rounded shape in cross-section.

10. The semiconductor device of claim 1,
wherein the at least one third portion comprises a first one of the third portions and a second one of the third portions on different side portions of the first portion, and
wherein the gate contact structure is between the first one of the third portions and the second one of the third portions of the stopper layer on the gate structure.

11. The semiconductor device of claim 10, further comprising:
an interconnection via structure that extends into the second portion of the stopper layer on the contact structure and is electrically connected to the contact structure.

12. The semiconductor device of claim 11,
wherein the at least one third portion further comprises a third one of the third portions and a fourth one of the third portions on different side portions of the second portion, and
wherein the interconnection via structure is between the second one of the third portions and the third one of the third portions of the stopper layer on the contact structure.

13. The semiconductor device of claim 12, further comprising:
an interconnection line structure on the gate contact structure and the interconnection via structure,
wherein at least a portion of the interconnection line structure is electrically connected to the gate contact structure, and
wherein at least a portion of the interconnection line structure is connected to the interconnection via structure.

14. A semiconductor device, comprising:
an active region that extends in a first direction on a substrate;
a plurality of channel layers spaced apart from each other in a vertical direction perpendicular to an upper surface of the substrate on the active region;
a gate structure including a gate electrode that intersects the active region and the plurality of channel layers on the substrate and extends around ones of the plurality of channel layers, a gate spacer on side surfaces of the gate electrode, and a gate capping layer on the gate electrode and the gate spacer, wherein the gate structure extends in a second direction;
a source/drain region on the active region, on a first side of the gate structure, and in contact with the ones of the plurality of channel layers; and
a contact structure on the source/drain region on the first side of the gate structure, electrically connected to the source/drain region, and extends in the second direction,
wherein an upper region of the gate capping layer of the gate structure has a first region and a second region on at least one end of the first region and has a rounded upper surface.

15. The semiconductor device of claim 14,
wherein an upper surface of the first region of the upper region of the gate capping layer and an upper surface of the contact structure are substantially flat, and
wherein the upper surface of the contact structure is lower than the upper surface of the first region of the upper region of the gate capping layer with respect to the substrate.

16. The semiconductor device of claim 15, wherein the upper surface of the contact structure is 3.5 nm to 4.0 nm lower than the upper surface of the first region of the upper region of the gate capping layer.

17. The semiconductor device of claim 15, further comprising:
a stopper layer on an upper surface of the upper region of the gate capping layer and an upper surface of the contact structure;
a gate contact structure that extends into the stopper layer and the gate capping layer on the gate structure and is electrically connected to the gate electrode of the gate structure; and
an interconnection via structure that extends into the stopper layer on the contact structure and is electrically connected to the contact structure.

18. The semiconductor device of claim 15, wherein an uppermost portion of the contact structure is between an upper surface of the gate capping layer and a lower surface of the gate capping layer.

19. A semiconductor device, comprising:
an active region that extends in a first direction on a substrate;
a plurality of channel layers spaced apart from each other in a vertical direction perpendicular to an upper surface of the substrate on the active region;
a gate structure including a gate electrode that intersects the active region and the plurality of channel layers and extends around ones of the plurality of channel layers, a gate spacer on side surfaces of the gate electrode, and a gate capping layer on the gate electrode and the gate spacer, and extends in a second direction,
wherein the gate capping layer of the gate structure has, in an upper region, a first region having a substantially flat upper surface and a second region on at least a first side of the first region and having a rounded upper surface;
a source/drain region on the active region on a first side of the gate structure and in contact with the plurality of channel layers;
a contact structure on the source/drain region on the first side of the gate structure, electrically connected to the source/drain region, and extends in the second direction; and
a stopper layer on the gate structure and the contact structure,
wherein the stopper layer comprises:
a first portion on the first region of the gate capping layer,
a second portion on an upper surface of the contact structure, and
a third portion that extends towards the substrate along the second region of the gate capping layer on at least one side of the first portion and electrically connected to a first side of the second portion.

20. The semiconductor device of claim 19, further comprising:
a gate contact structure that extends into the first portion of the stopper layer and into the gate capping layer and is electrically connected to the gate electrode;
an interconnection via structure that extends into the second portion of the stopper layer and is electrically connected to the contact structure; and
interconnection line structures on the gate contact structure and on the interconnection via structure, and electrically connected to the gate contact structure and the interconnection via structure, respectively.
